(19) United States
(12) Patent Application Publication
(10) Pub. No.: US 2008/0188024 A1
(43) Pub. Date: Aug. 7, 2008

(54) METHOD OF FABRICATING MICRO MECHANICAL MOVING MEMBER AND METAL INTERCONNECTS THEREOF

(76) Inventors: Kuan-Jui Huang, Kao-Hsiung Hsien (TW); Hsiu-Ming Li, Taipei County (TW); Shih-Min Huang, Taipei City (TW); Chia-Chun Chen, Kaohsiung County (TW); Hui-Chen Kuo, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 11/735,498

(22) Filed: Apr. 16, 2007

(30) Foreign Application Priority Data
Feb. 6, 2007 (TW) 096104292

(51) Int. Cl. H01L 21/00

(52) U.S. Cl. 438/48

(57) ABSTRACT

A method of fabricating micro mechanical moving member and metal interconnects thereof. A first metal interconnect pattern and a second metal interconnect pattern disposed thereon are formed on a substrate by plating processes. Subsequently, an inter-metal dielectric layer is formed on the substrate, the first metal interconnect pattern and the second metal interconnect pattern. The inter-metal dielectric layer is then planarized and the second metal interconnect pattern is exposed. After that, at least one micro mechanical moving member electrically connected to the second metal interconnect pattern is formed on the inter-metal dielectric layer by plating techniques.

### BACKGROUND OF THE INVENTION

1. Field of the Invention

The present invention relates to a method of fabricating micro mechanical moving member and metal interconnects thereof, and more particularly, to a method of fabricating metal interconnects with reduced resistance, which can be integrated into metal interconnection process and micro mechanical moving member fabrication.

2. Description of the Prior Art

In current MEMS fabrications, conducting wires (interconnections) and micro mechanical structures are two main parts. Compared to semiconductor devices, the MEMS devices need larger current to drive, and thus the conducting wires have to meet a high-current requirement. This high-current requirement makes the MEMS device require smaller resistance. In another aspect, however, the miniaturation of MEMS devices is also trendy. Considering the miniaturation, to reduce the resistance of conducting wires turns out to be a problem to solve.

### SUMMARY OF THE INVENTION

It is therefore one object of the claimed invention to provide a method of fabricating micro mechanical moving member and metal interconnects thereof.

It is another objective of the claimed invention to provide a method of fabricating inter-metal dielectric layer able to meet different requirements and applications.

According to a preferred embodiment of the present invention, a method of fabricating micro mechanical moving member and metal interconnects thereof is provided. The method includes:

providing a substrate;

forming a first sacrificial pattern having a plurality of first openings on the substrate;

performing a first plating process to form a first metal interconnect pattern in each of the first openings;

removing the first sacrificial pattern, and forming a second sacrificial pattern on the substrate and on the first metal interconnect pattern, the second sacrificial pattern having a plurality of second openings partially exposing the first metal interconnect pattern;

performing a second plating process to form a second metal interconnect pattern in each of the second openings;

removing the second sacrificial pattern;

forming an inter-metal dielectric layer on the substrate, the first metal interconnect pattern and the second metal interconnect pattern;

planarizing the surface of the inter-metal dielectric layer to expose the second metal interconnect pattern; and

forming at least one micro mechanical moving member, which electrically connects to the second metal interconnect pattern, on the inter-metal dielectric layer by plating techniques.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-13 are schematic diagrams illustrating a method of fabricating micro mechanical moving member and metal interconnects thereof in according to a preferred embodiment of the present invention.

### DETAILED DESCRIPTION

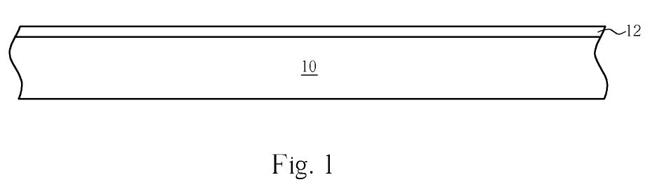

Please refer to FIGS. 1-13. FIGS. 1-13 are schematic diagrams illustrating a method of fabricating micro mechanical moving member and metal interconnects thereof in according to a preferred embodiment of the present invention. As shown in FIG. 1, a substrate 10 e.g. a semiconductor wafer, is provided. The substrate 10 may includes fabricated electronic devices (not shown). A thermal oxide layer 12 is then formed on the surface of the substrate 10. The thermal oxide layer 12 serves as a stress buffer layer for avoiding stress issue, and also serves as a diffusion barrier layer for avoiding diffusion of metal subsequently formed. In other embodiments, the thermal oxide layer 12 may be omitted wherever necessary.

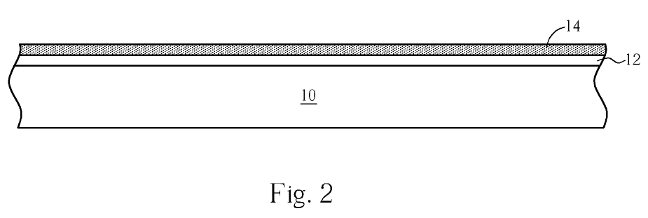

As shown in FIG. 2, a seed layer 14 is formed on the surface of the thermal oxide layer 12. The seed layer 14 may be formed by sputtering or other deposition techniques. The material of the seed layer 14 may be a TiW/Cu thin film, a Cr/Au thin film, a Ti/Au thin film, etc. to meet different requirements. In the instant embodiment, the thickness of the seed layer 14 is 50-250 angstroms/1000-2000 angstroms (for two thin films), but the thickness of the seed layer 14 may be modified according to different conditions.

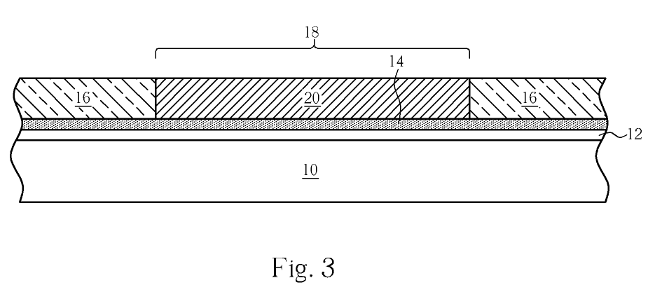

As shown in FIG. 3, a first sacrificial layer 16, such as a photoresist pattern, is formed on the seed layer 14, and the first sacrificial layer 16 has a plurality of first openings 18. Subsequently, a first plating process is carried out to form a first metal interconnect pattern 20 in each of the first openings 18. In this embodiment, the first plating process includes an electroplating process or a non-electroplating process, and copper is used as the material of the first metal interconnect pattern 20. The dimension (e.g. line width) and the thickness of the first metal interconnect pattern 20 may be modified to meet different resistance requirements. For instance, the dimension of the first metal interconnect pattern 20 is approximately 10 micrometers, and the thickness is approximately 4-6 micrometers. It is to be appreciated that the material of the first metal interconnect pattern 20 is not limited to copper, and the dimension and thickness are not limited in the aforementioned range. In addition, the process parameters of the first plating process, e.g. process time, is controlled so that the thickness of the first metal interconnect pattern 20 does not exceed the thickness of the first sacrificial pattern 16.

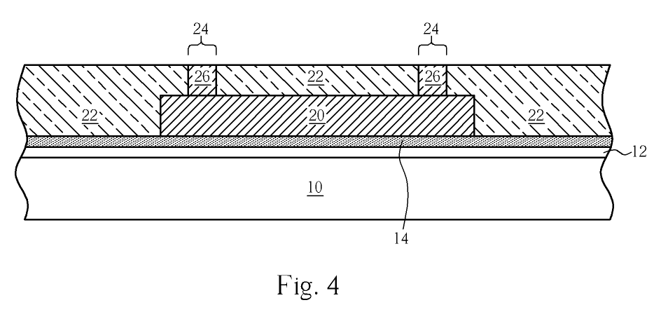

As shown in FIG. 4, the first sacrificial pattern 16 is removed, and a second sacrificial pattern 22 e.g. a photoresist pattern is formed on the thermal oxide layer 12 and the first metal interconnect pattern 20. The second sacrificial pattern 22 has a plurality of second openings 24 partially exposing the first metal interconnect pattern 20. Subsequently, a second plating process is performed to form a second metal interconnect pattern 26 in each of the second openings 24. In this embodiment, the second metal interconnect pattern 26 is a plug layer, made of copper and formed by an electroplating process or a non-electroplating process. The thickness of the second metal interconnect pattern 26 is approximately 4-6 micrometers. The material of the second metal interconnect pattern 26 is not limited to copper, and the thickness of the second metal interconnect pattern 26 is not limited to the aforementioned range. Also, the thickness of the second metal interconnect pattern 26 may not exceed the thickness of the second sacrificial pattern 22.

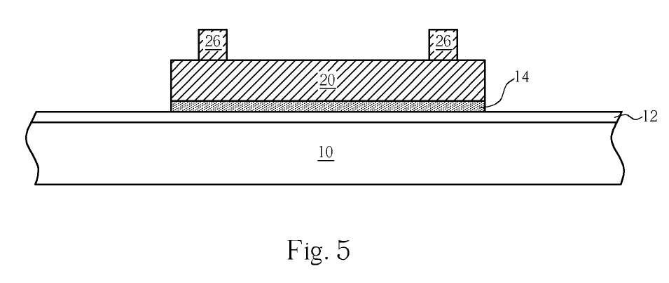

As shown in FIG. 5, the second sacrificial pattern 22 and the seed layer 14 not covered by the first metal interconnect pattern 20 are removed. After that, a surface treatment may be implemented to remove residues e.g. oxide compound remaining on the surface of the first metal interconnect pattern 20 and the second metal interconnect pattern 26.

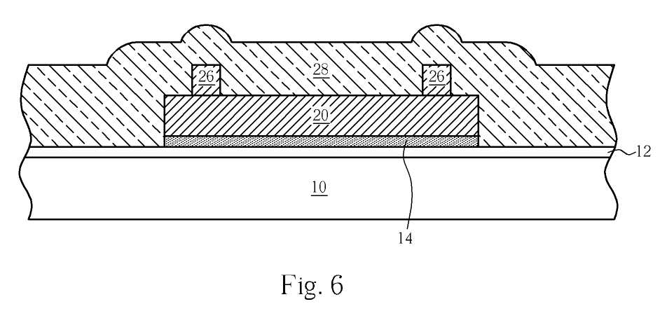

As shown in FIG. 6, an inter-metal dielectric layer 28 is formed on the surface of the first metal interconnect pattern 20, the second metal interconnect pattern 26, and the thermal oxide layer 12. In the present embodiment, the inter-metal dielectric layer 28 is a silicon oxide layer formed by a plasma enhanced chemical vapor deposition (PECVD) process, and the thickness of the inter-metal dielectric layer 28 is substantially over 11 micrometers.

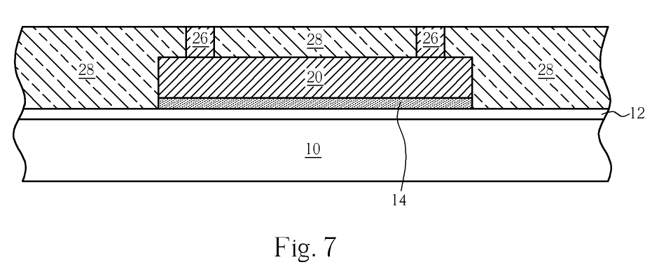

As shown in FIG. 7, the surface of the inter-metal dielectric layer 28 is planarized to expose the second metal interconnect pattern 26. In this embodiment, the planarization of the inter-metal dielectric layer 28 is implemented by a chemical mechanical polishing (CMP) process, but not limited. The planarization may also be done by other techniques such as etching.

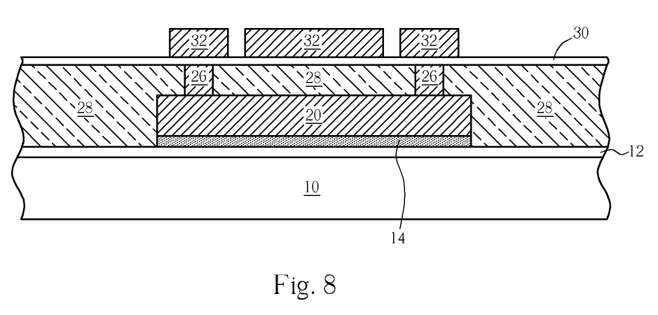

The first metal interconnect pattern 20 is used as the first layer metal interconnection, and the second metal interconnect pattern 26 serves as the plug layer. Nevertheless, the method of the present invention is not limited to fabricate a single-layered metal interconnection. The aforementioned steps can be repeated to form a two-layered or multi-layered metal interconnection wherever necessary. An example of forming a two-layered metal interconnection is illustrated as follows. As shown in FIG. 8, a surface treatment e.g. an etching process is performed before fabricating the second metal interconnection. The surface treatment is able to remove residues such as oxide compounds or organic compound remaining on the surface of the second metal interconnect pattern 26 and the inter-metal dielectric layer 28. Subsequently, another seed layer 30 is formed on the surface of the second metal interconnect pattern 26 and the inter-metal dielectric layer 28. The material and thickness of the seed layer 30 may be similar to that of the seed layer 14 or modified where necessary. Following that, a third metal interconnect pattern 32 is formed on the inter-metal dielectric layer 28 and the second metal interconnect pattern 26 by electroplating or non-electroplating techniques.

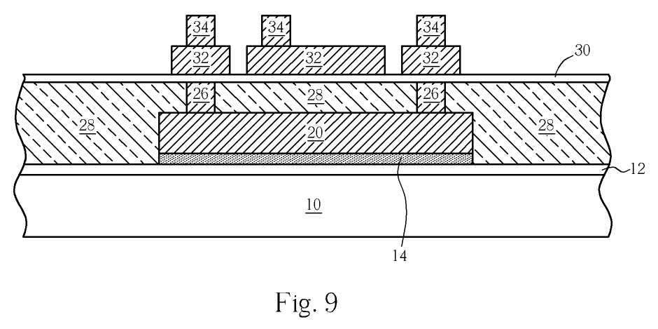

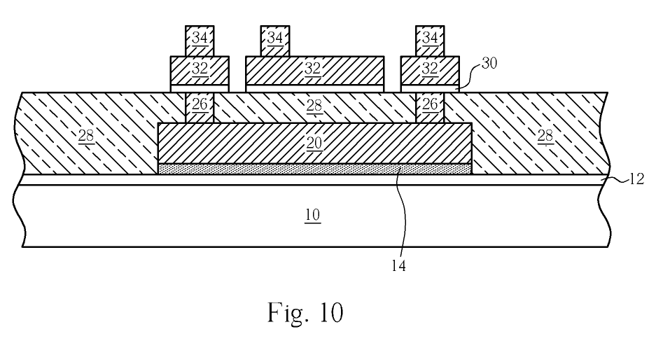

As shown in FIG. 9, a fourth metal interconnect pattern 34 is formed on the third metal interconnect pattern 32. The third metal interconnect pattern 32 serves as the second layer metal interconnection, and the fourth metal interconnect pattern 34 serves as a plug layer. As shown in FIG. 10, the seed layer 30 not covered by the third metal interconnect pattern 32 and the fourth metal interconnect pattern 34.

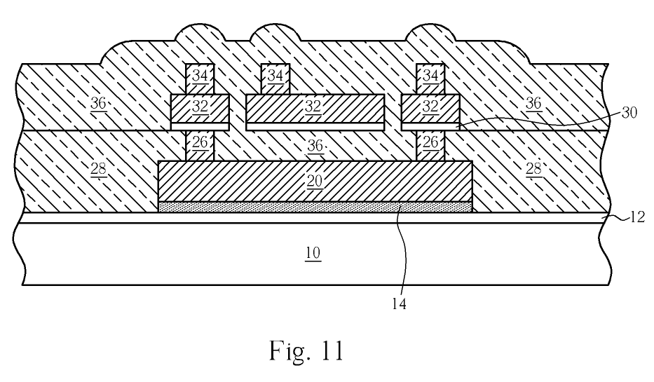

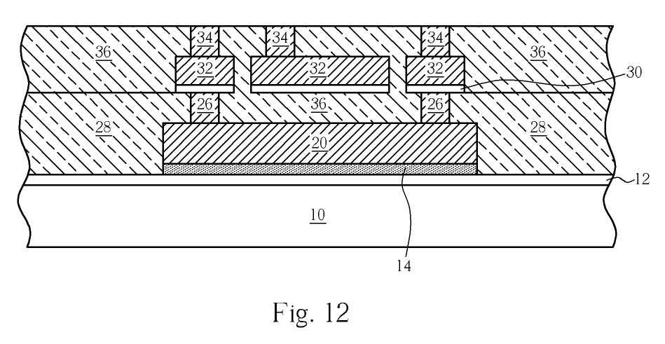

As shown in FIG. 11, another inter-metal dielectric layer 36 is formed on the third metal interconnect pattern 32 and the fourth metal interconnect pattern 34. In the instant embodiment, the inter-metal dielectric layer 36 is a silicon oxide layer formed by a PECVD process. As shown in FIG. 12, the inter-metal dielectric layer 36 is planarized to expose the fourth metal interconnect pattern 34 for the convenience of connecting micro mechanical moving member that is to be formed subsequently. In the instant embodiment, the planarization is achieved by a CMP process, but not limited.

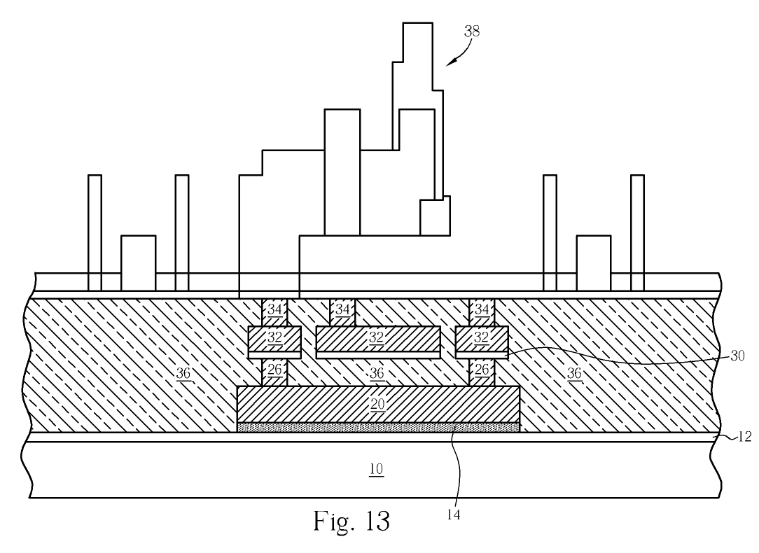

As shown in FIG. 13, at least one micro mechanical moving member 38, such as a micro actuator, a micro relay or a micro sensor, is formed on the inter-metal dielectric layer 36 by electroplating or non-electroplating techniques. The micro mechanical moving member 38 is electrically connected to the third metal interconnect pattern 32, the second metal interconnect pattern 26, and the first metal interconnect pattern 20 via the fourth metal interconnect pattern 34, and therefore driven by control devices (not shown) which is electrically connected to the first metal interconnect pattern 20.

The benefits and features of the method of the present invention is summarized as follows. First, the present invention rapidly fabricates the micro interconnection module, which electrically communicating with the micro mechanical structure or moving member, thereby reducing the package area and improving integration of MEMS system. Second, the interconnection of the present invention has a thickness (greater than 1 micrometer), thereby reducing the resistance of metal interconnection. In addition, the dimension, pattern design and layout can be modified to meet different requirements. Furthermore, the micro mechanical moving member disposed over the metal interconnection can be directly electrically connected to the metal interconnection.

Those skilled in the art will readily observe that numerous modifications and alterations of the device and method may be made while retaining the teachings of the invention.

What is claimed is:

1. A method of fabricating micro mechanical moving member and metal interconnects thereof, comprising:
providing a substrate;
forming a first sacrificial pattern having a plurality of first openings on the substrate;
performing a first plating process to form a first metal interconnect pattern in each of the first openings;
removing the first sacrificial pattern, and forming a second sacrificial pattern on the substrate and on the first metal interconnect pattern, the second sacrificial pattern having a plurality of second openings partially exposing the first metal interconnect pattern;
performing a second plating process to form a second metal interconnect pattern in each of the second openings;
removing the second sacrificial pattern;
forming an inter-metal dielectric layer on the substrate, the first metal interconnect pattern and the second metal interconnect pattern;
planarizing the surface of the inter-metal dielectric layer to expose the second metal interconnect pattern; and
forming at least one micro mechanical moving member, which electrically connects to the second metal interconnect pattern, on the inter-metal dielectric layer by plating techniques.

2. The method of claim 1, further comprising forming a thermal oxide layer on the substrate prior to forming the first sacrificial pattern.

3. The method of claim 1, wherein the first metal interconnect pattern and the second metal interconnect pattern comprise copper.

4. The method of claim 1, wherein the first plating process comprises an electroplating process or a non-electroplating process.

5. The method of claim 1, wherein the second plating process comprises an electroplating process or a non-electroplating process.

6. The method of claim 1, further comprising forming a seed layer on the substrate prior to performing the first plating process.

7. The method of claim 1, wherein the inter-metal dielectric layer is a silicon oxide layer.

8. The method of claim 1, wherein the inter-metal dielectric layer is formed on the substrate, the first metal interconnect pattern and the second metal interconnect pattern by a plasma enhanced chemical vapor deposition (PECVD) process.

9. The method of claim 1, wherein planarizing the surface of the inter-metal dielectric layer to expose the second metal interconnect pattern is achieved by a chemical mechanical polishing (CMP) process.

10. The method of claim 1, wherein the second metal interconnect pattern is a plug layer.
